(19) United States
(12) Patent Application Publication
(10) Pub. No.: US 2015/0357242 A1
(43) Pub. Date: Dec. 10, 2015

(54) WAFER PROCESSING METHOD

(71) Applicant: DISCO CORPORATION, Tokyo (JP)

(72) Inventor: Masaru Nakamura, Tokyo (JP)

(21) Appl. No.: 14/735,888

(22) Filed: Jun. 10, 2015

(30) Foreign Application Priority Data
Jun. 10, 2014 (JP) 2014-119409

(51) Int. Cl. H01L 21/78; H01L 21/304; H01L 21/02; H01L 21/683

(52) U.S. Cl. CPC H01L 21/78; H01L 21/6836; H01L 21/304; H01L 21/02076; H01L 2221/68327; H01L 2221/68381

(57) ABSTRACT

A wafer is divided into individual device chips along crossing division lines, the division lines being formed on the front side of the wafer to thereby define separate regions where devices are respectively formed. A division groove having a depth corresponding to the finished thickness of each device chip is formed along each division line on the front side of the wafer. The back side of the wafer is ground until the division groove along each division line is exposed to the back side of the wafer, thereby dividing the wafer into the individual device chips. An adhesive film for die bonding is mounted on the back side of the wafer and a dicing tape is attached to the adhesive film. The dicing tape is expanded to thereby break the adhesive film along the individual device chips.

### BACKGROUND OF THE INVENTION

1. Field of the Invention

The present invention relates to a wafer processing method of dividing a wafer into a plurality of individual device chips along a plurality of crossing division lines (streets) and mounting an adhesive film for die bonding on the back side of each device chip, the plurality of crossing division lines being formed on the front side of the wafer to thereby define a plurality of separate regions where a plurality of devices are respectively formed.

2. Description of the Related Art

In a semiconductor device fabrication process, a plurality of crossing division lines (streets) are formed on the front side of a substantially disk-shaped semiconductor wafer to thereby define a plurality of separate regions where a plurality of devices such as ICs and LSIs are respectively formed, and these regions are divided from each other along the streets to thereby produce a plurality of individual semiconductor device chips. As a dividing apparatus for dividing the semiconductor wafer into the individual semiconductor device chips, a dicing saw is generally used. The dicing saw includes a cutting blade having a thickness of about 20 μm to 30 μm for cutting the semiconductor wafer along the streets. The semiconductor device chips thus obtained are packaged to be widely used in electric equipment such as mobile phones and personal computers.

As a technique of dividing the semiconductor wafer into the individual semiconductor device chips, a so-called dicing before grinding process has been put to practical use. This dicing before grinding process includes the steps of forming a kerf (division groove) having a predetermined depth (corresponding to the finished thickness of each semiconductor device chip) along each street on the front side of the semiconductor wafer and next grinding the back side of the semiconductor wafer to expose each kerf to the back side of the semiconductor wafer, thereby dividing the semiconductor wafer into the individual semiconductor device chips. By this dicing before grinding process, the thickness of each semiconductor device chip can be reduced to 50 μm or less (see Japanese Patent Laid-open No. 2003-7648, for example).

An adhesive film for die bonding called a die attach film (DAF) having a thickness of 20 μm to 40 μm is mounted on the back side of each semiconductor device chip, and each semiconductor device chip is bonded through the adhesive film to a die bonding frame for supporting the semiconductor device chip by heating. The adhesive film is formed of polyimide resin, epoxy resin, or acrylic resin, for example.

However, in the condition where the adhesive film for die bonding is mounted on the back side of the semiconductor wafer, the semiconductor wafer cannot be divided by the dicing before grinding process mentioned above. To solve this problem, there has been proposed a method including the steps of mounting an adhesive film for die bonding on the back side of a semiconductor wafer divided into individual semiconductor device chips by the dicing before grinding process, attaching the adhesive film to a dicing tape, and expanding the dicing tape to thereby break the adhesive film along the individual semiconductor device chips (see Japanese Patent Laid-open No. 2008-235650, for example).

### SUMMARY OF THE INVENTION

However, in the case of mounting the adhesive film on the back side of the semiconductor wafer divided into the individual semiconductor device chips, next attaching the adhesive film to the dicing tape, and next expanding the dicing tape to thereby break the adhesive film along the individual semiconductor device chips as mentioned above, there is a problem such that since the adhesive film has a size slightly larger than the size of the semiconductor wafer, the peripheral portion of the adhesive film may be finely crushed to scatter in the step of breaking the adhesive film, so that a crushed part of the peripheral portion of the adhesive film may stick to the front side of the semiconductor device chips.

Furthermore, there is a possibility that such a crushed part of the adhesive film may stick to electrodes exposed to the front side of the semiconductor device chips, causing the hindrance to wire bonding and the occurrence of faulty continuity to result in a reduction in quality of the semiconductor device chips.

It is therefore an object of the present invention to provide a wafer processing method which can solve the problem that the finely crushed part of the adhesive film for die bonding may directly stick to the front side of the semiconductor device chips in the step of breaking the adhesive film along the individual semiconductor device chips, wherein the adhesive film is mounted on the back side of a semiconductor wafer divided into the individual semiconductor device chips by the dicing before grinding process mentioned above.

In accordance with an aspect of the present invention, there is provided a wafer processing method of dividing a wafer into a plurality of individual device chips along a plurality of crossing division lines and mounting an adhesive film for die bonding on the back side of each device chip, the plurality of crossing division lines being formed on the front side of the wafer to thereby define a plurality of separate regions where a plurality of devices are respectively formed, the wafer processing method including a division groove forming step of forming a division groove having a depth corresponding to the finished thickness of each device chip along each division line on the front side of the wafer; a protective film forming step of applying a water-soluble resin to the front side of the wafer after performing the division groove forming step, thereby forming a protective film from the water-soluble resin on the front side of the wafer; a protective member attaching step of attaching a protective member to the front side of the protective film after performing the protective film forming step; a back grinding step of grinding the back side of the wafer until the division groove along each division line is exposed to the back side of the wafer after performing the protective member attaching step, thereby dividing the wafer into the individual device chips; a wafer supporting step of mounting the adhesive film on the back side of the wafer after performing the back grinding step, attaching a dicing tape to the adhesive film, supporting the peripheral portion of the dicing tape to an annular frame, and peeling the protective member attached to the front side of the wafer; an adhesive film breaking step of expanding the dicing tape to thereby break the adhesive film along the individual device chips after performing the wafer supporting step; and a protective film removing step of supplying a cleaning water to the protective film formed on the front side of the wafer after performing the adhesive film breaking step, thereby removing the protective film.

In the adhesive film breaking step of the wafer processing method according to the present invention, there is a possibility that the peripheral portion of the adhesive film projecting from the outer circumference of the wafer may be partially crushed to scatter, so that a crushed part of the peripheral portion of the adhesive film may fall on the front side of the devices. However, since the protective film is formed on the front side of the devices, the crushed part of the peripheral portion of the adhesive film sticks to the front side of the protective film formed on the front side of the devices, and there is no possibility that the crushed part of the peripheral portion of the adhesive film may directly stick to the front side of the devices. Accordingly, by supplying a cleaning water to the protective film formed on the front side of the devices to remove the protective film in the next step, the crushed part sticking to the protective film can be removed together with the protective film, thereby preventing a reduction in quality of the devices.

Further, in forming the protective film on the front side of the wafer in the protective film forming step, all of the division grooves formed on the front side of the wafer are filled with the water-soluble resin in the liquid form. Accordingly, in performing the back grinding step, the movement of each device chip is restricted to thereby prevent the chipping of each device chip. Furthermore, it is possible to prevent a problem such that a grinding water containing a grinding dust may enter the division grooves to cause the contamination of the front side of the device chips.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a semiconductor wafer;

FIGS. 2A and 2B are views for illustrating a division groove forming step;

FIGS. 3A to 3C are views for illustrating a protective film forming step;

FIGS. 4A and 4B are perspective views for illustrating a protective member attaching step;

FIGS. 5A to 5C are views for illustrating a back grinding step;

FIGS. 6A to 6C are perspective views for illustrating a first preferred embodiment of a wafer supporting step;

FIGS. 7A and 7B are perspective views for illustrating a second preferred embodiment of the wafer supporting step;

FIG. 8 is a perspective view of a tape expanding apparatus for performing an adhesive film breaking step;

FIGS. 9A and 9B are sectional side views for illustrating the adhesive film breaking step; and

FIGS. 10A and 10B are sectional side views for illustrating a protective film removing step.

### DETAILED DESCRIPTION OF THE PREFERRED EMBODIMENTS

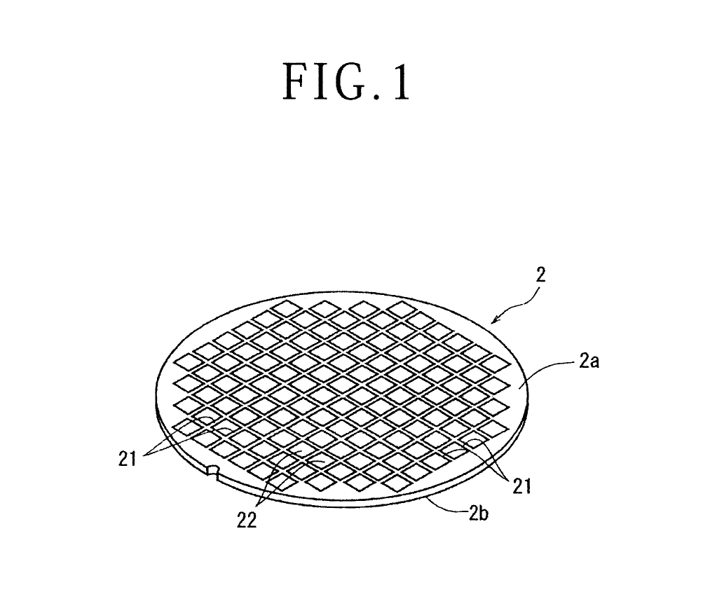

Preferred embodiments of the wafer processing method according to the present invention will now be described in detail with reference to the attached drawings. FIG. 1 is a perspective view of a semiconductor wafer 2. The semiconductor wafer 2 shown in FIG. 1 is formed from a silicon wafer having a thickness of 500 μm, for example. The semiconductor wafer 2 has a front side 2a and a back side 2b. A plurality of crossing division lines 21 are formed on the front side 2a of the semiconductor wafer 2 to thereby define a plurality of separate regions where a plurality of devices 22 such as ICs and LSIs are respectively formed. There will now be described a wafer processing method of dividing the semiconductor wafer 2 into the individual devices (device chips) 22 along the division lines 21 and mounting an adhesive film for die bonding on the back side of each device 22.

First, there will now be described a method of dividing the semiconductor wafer 2 into the individual device chips 22 by using a so-called dicing before grinding process.

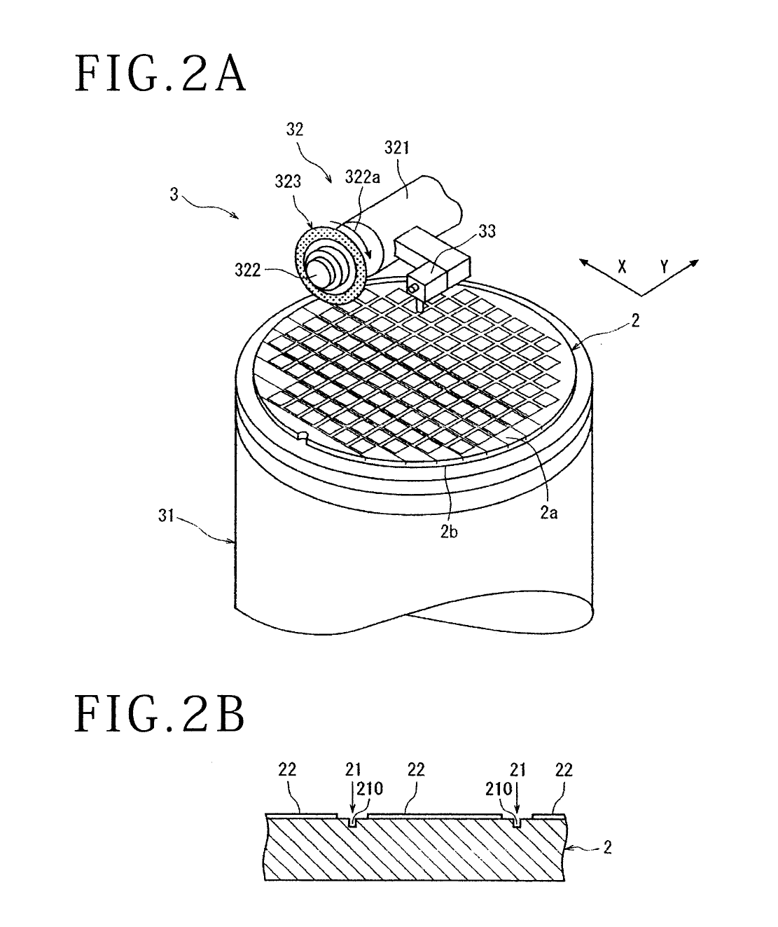

In the method of dividing the semiconductor wafer 2 into the individual device chips 22 by using the dicing before grinding process, a division groove having a predetermined depth (corresponding to the finished thickness of each device chip 22) is formed along each division line 21 on the front side 2a of the semiconductor wafer 2 (division groove forming step). This division groove forming step is performed by using a cutting apparatus 3 shown in FIG. 2A. The cutting apparatus 3 shown in FIG. 2A includes a chuck table 31 for holding a workpiece, cutting means 32 for cutting the workpiece held on the chuck table 31, and imaging means 33 for imaging the workpiece held on the chuck table 31. The chuck table 31 has an upper surface for holding the workpiece under suction. The chuck table 31 is movable both in a feeding direction shown by an arrow X in FIG. 2A by a feeding mechanism (not shown) and in an indexing direction shown by an arrow Y in FIG. 2A by an indexing mechanism (not shown).

The cutting means 32 includes a spindle housing 321 extending in a substantially horizontal direction, a rotating spindle 322 rotatably supported to the spindle housing 321, and a cutting blade 323 mounted on the front end portion of the rotating spindle 322. The rotating spindle 322 is rotatable in the direction shown by an arrow 322a by a servo motor (not shown) provided in the spindle housing 321. The thickness of the cutting blade 323 is set to 30 μm, for example. The imaging means 33 includes illuminating means for illuminating the workpiece, an optical system for capturing an area illuminated by the illuminating means, and an imaging device (CCD) for detecting an image in the area captured by the optical system. An image signal output from the imaging means 33 is transmitted to control means (not shown).

In performing the division groove forming step by using the cutting apparatus 3 mentioned above, the semiconductor wafer 2 is placed on the chuck table 31 in the condition where the back side 2b of the semiconductor wafer 2 is in contact with the upper surface of the chuck table 31 as shown in FIG. 2A. Thereafter, suction means (not shown) is operated to hold the semiconductor wafer 2 on the chuck table 31 under suction. Accordingly, the semiconductor wafer 2 is held on the chuck table 31 under suction in the condition where the front side 2a of the semiconductor wafer 2 is oriented upward. Thereafter, the chuck table 31 holding the semiconductor wafer 2 is moved to a position directly below the imaging means 33 by operating the feeding mechanism (not shown).

In the condition where the chuck table 31 is positioned directly below the imaging means 33, an alignment operation is performed by the imaging means 33 and the control means (not shown) to detect a cutting area where the division groove is to be formed along each division line 21 of the semiconductor wafer 2. More specifically, the imaging means 33 and the control means (not shown) perform image processing such as pattern matching for making the alignment between the cutting blade 323 and the division lines 21 extending in a first direction on the semiconductor wafer 2, thereby performing the alignment for the cutting area (alignment step). This alignment step is similarly performed for the other division lines 21 extending in a second direction perpendicular to the first direction on the semiconductor wafer 2.

After performing the alignment step mentioned above to detect the cutting area along all of the division lines 21 of the semiconductor wafer 2 held on the chuck table 31, the chuck table 31 holding the semiconductor wafer 2 is moved to a cutting start position where one end of a predetermined one of the division lines 21 is positioned directly below the cutting blade 323. At this cutting start position, the cutting blade 323 is rotated in the direction of the arrow 322a in FIG. 2A and then lowered to cut into the semiconductor wafer 2. The depth of cut by the cutting blade 323 into the semiconductor wafer 2 is set so that the outer circumference of the cutting blade 323 reaches a predetermined depth (e.g., 50 μm) corresponding to the finished thickness of each device chip 22 as measured from the front side 2a of the semiconductor wafer 2. Thereafter, the chuck table 31 is fed in the direction of the arrow X in FIG. 2A as rotating the cutting blade 323, thereby forming a division groove 210 along the predetermined division line 21 on the front side 2a of the semiconductor wafer 2 as shown in FIG. 2B, wherein the division groove 210 has a width of 30 μm and a depth of 50 μm, for example, corresponding to the finished thickness of each device chip 22 (division groove forming step). This division groove forming step is similarly performed along all of the other division lines 21 to form similar division grooves 210.

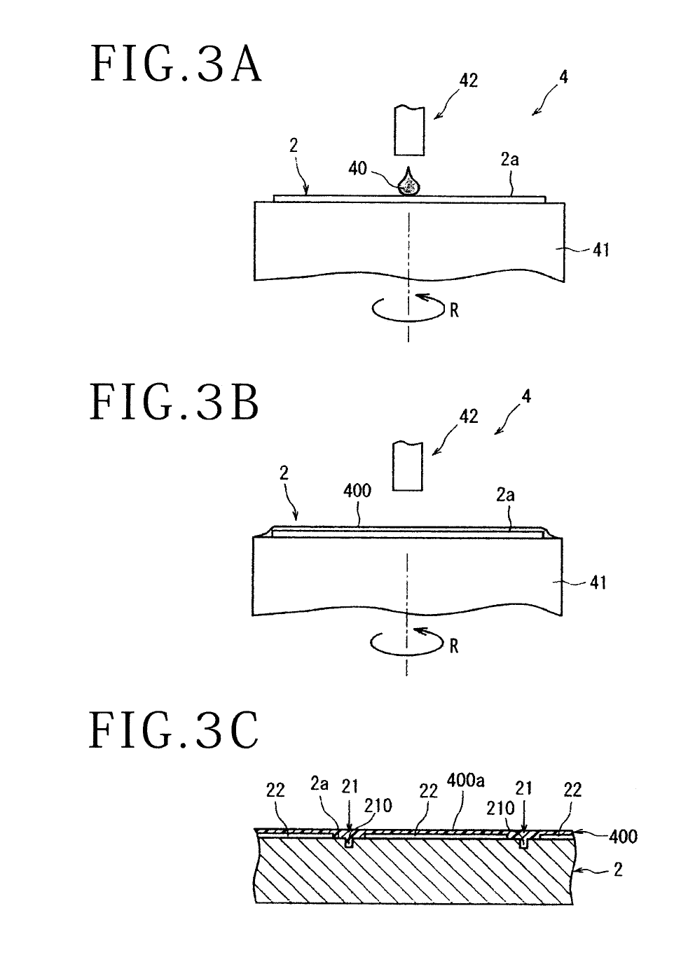

After performing the division groove forming step mentioned above, a protective film forming step is performed in such a manner that a water-soluble resin is applied to the front side 2a of the semiconductor wafer 2, thereby forming a protective film from the water-soluble resin on the front side 2a of the semiconductor wafer 2. This protective film forming step is performed by using a protective film forming apparatus 4 shown in FIGS. 3A and 3B. The protective film forming apparatus 4 includes a spinner table 41 for holding a workpiece and a liquid resin nozzle 42 located above the center of rotation of the spinner table 41. The semiconductor wafer 2 processed by the division groove forming step mentioned above is placed on the spinner table 41 of the protective film forming apparatus 4 in the condition where the back side 2b of the semiconductor wafer 2 is in contact with the upper surface of the spinner table 41. Thereafter, suction means (not shown) is operated to hold the semiconductor wafer 2 on the spinner table 41 under suction. Accordingly, the semiconductor wafer 2 is held on the spinner table 41 under suction in the condition where the front side 2a of the semiconductor wafer 2 is oriented upward.

After holding the semiconductor wafer 2 on the spinner table 41 under suction as mentioned above, the spinner table 41 is rotated in the direction shown by an arrow R in FIG. 3A at a predetermined speed (e.g., 300 rpm to 1000 rpm), and at the same time a predetermined amount of water-soluble resin 40 in the form of a liquid is dropped from the liquid resin nozzle 42 located above the spinner table 41 to the central area of the front side 2a of the semiconductor wafer 2 as shown in FIG. 3A. Thereafter, the spinner table 41 is rotated for about 60 seconds to thereby form a protective film 400 on the front side 2a of the semiconductor wafer 2 as shown in FIGS. 3B and 3C. In forming the protective film 400, all of the division grooves 210 formed on the front side 2a of the semiconductor wafer 2 are filled with the water-soluble resin 40 in the liquid form. The thickness of the protective film 400 to be formed on the front side 2a of the semiconductor wafer 2 is typically set to about 50 μm, depending upon the amount of the water-soluble resin 40 to be dropped. Examples of the water-soluble resin 40 include polyvinyl alcohol (PVA), water-soluble phenol resin, and acrylic water-soluble resin.

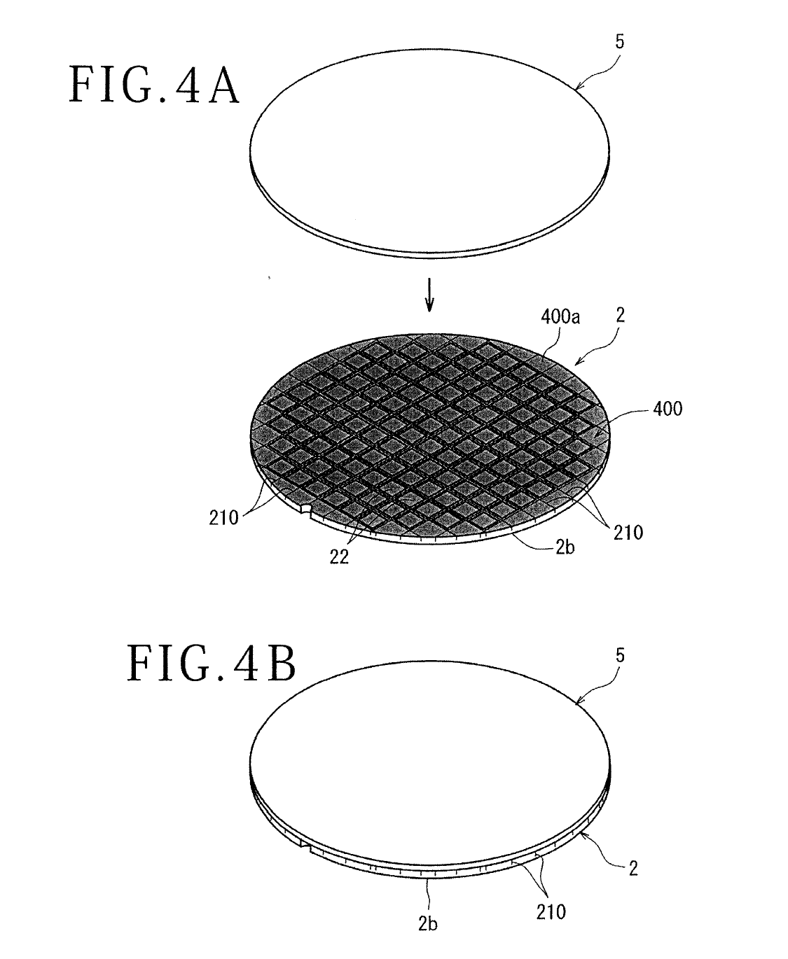

After drying to solidify the protective film 400 formed on the front side 2a of the semiconductor wafer 2 in the protective film forming step mentioned above, a protective member attaching step is performed in such a manner that a protective member is attached to the front side 400a of the protective film 400. More specifically, as shown in FIGS. 4A and 4B, a protective tape 5 as the protective member is attached to the front side 400a of the protective film 400 formed on the front side 2a of the semiconductor wafer 2. The protective tape 5 is composed of a base sheet and an adhesive layer formed on the base sheet. For example, the base sheet is formed of polyvinyl chloride (PVC) and has a thickness of 100 μm, and the adhesive layer is formed of acrylic resin and has a thickness of about 5 μm.

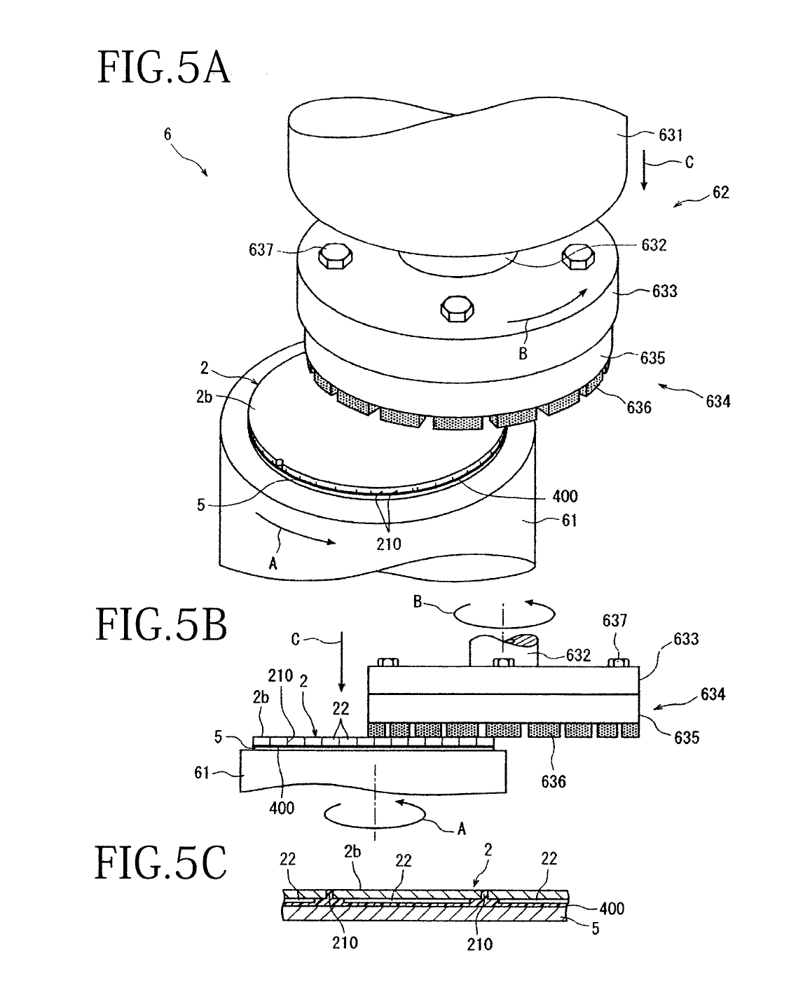

After performing the protective member attaching step, a back grinding step is performed in such a manner that the back side 2b of the semiconductor wafer 2 is ground as supplying a grinding water to reduce the thickness of the wafer 2 to a predetermined thickness until the division grooves 210 are exposed to the back side 2b of the wafer 2, thereby dividing the semiconductor wafer 2 into the individual device chips 22. This back grinding step is performed by using a grinding apparatus 6 shown in FIG. 5A. The grinding apparatus 6 shown in FIG. 5A includes a chuck table 61 as holding means for holding a workpiece and grinding means 62 for grinding the workpiece held on the chuck table 61. The chuck table 61 has an upper surface for holding the workpiece under suction. The chuck table 61 is rotatable in the direction shown by an arrow A in FIG. 5A by a rotationally driving mechanism (not shown). The grinding means 62 includes a spindle housing 631, a rotating spindle 632 rotatably supported to the spindle housing 631 and adapted to be rotated in the direction shown by an arrow B in FIG. 5A by a rotationally driving mechanism (not shown), a mounter 633 fixed to the lower end of the rotating spindle 632, and a grinding wheel 634 mounted on the lower surface of the mounter 633. The grinding wheel 634 is composed of an annular base 635 and a plurality of abrasive members 636 fixed to the lower surface of the annular base 635 so as to be annularly arranged along the outer circumference thereof. The annular base 635 is mounted on the lower surface of the mounter 633 by a plurality of fastening bolts 637. Although not shown, a grinding water passage is formed in the rotating spindle 632 along the axis thereof, so that a grinding water is supplied through the grinding water passage to a grinding area to be ground by the abrasive members 636.

In performing the back grinding step by using the grinding apparatus 6 mentioned above, the semiconductor wafer 2 is placed on the chuck table 61 in the condition where the protective tape 5 attached to the front side 2a of the semiconductor wafer 2 (the protective film 400 being interposed therebetween) is in contact with the upper surface (holding surface) of the chuck table 61. Thereafter, suction means (not shown) is operated to hold the semiconductor wafer 2 through the protective tape 5 on the chuck table 61 under suction (wafer holding step). Accordingly, the semiconductor wafer 2 is held through the protective tape 5 on the chuck table 61 under suction in the condition where the back side 2b of the semiconductor wafer 2 is oriented upward. After holding the semiconductor wafer 2 through the protective tape 5 on the chuck table 61 under suction as mentioned above, the chuck table 61 is rotated in the direction of the arrow A in FIG. 5A at 300 rpm, for example. At the same time, the grinding wheel 634 of the grinding means 62 is also rotated in the direction of the arrow B in FIG. 5A at 6000 rpm, for example. Thereafter, the grinding means 62 is lowered to bring the abrasive member 636 of the grinding wheel 634 into contact with the back side 2b (work surface) of the semiconductor wafer 2. Thereafter, the grinding wheel 634 is fed (lowered) in the direction shown by an arrow C in FIG. 5B (in the direction perpendicular to the holding surface of the chuck table 61) by a predetermined amount at a feed speed of 1 μm/second, for example.

Accordingly, the back side 2b of the semiconductor wafer 2 is ground until the division grooves 210 are exposed, so that the semiconductor wafer 2 is divided into the individual device chips 22 as shown in FIGS. 5B and 5C. At this time, the individual device chips 22 are kept in the form of the semiconductor wafer 2 because the protective tape 5 is attached to the front side of these device chips 22 with the protective film 400 interposed therebetween. In forming the protective film 400 on the front side 2a of the semiconductor wafer 2 in the protective film forming step mentioned above, all of the division grooves 210 are filled with the water-soluble resin 40 in the liquid form. Accordingly, in performing the back grinding step, the movement of each device chip 22 is restricted to thereby prevent the chipping of each device chip 22. Furthermore, it is possible to prevent the problem that the grinding water containing a grinding dust may enter the division grooves 210 to cause the contamination of the front side of the device chips 22.

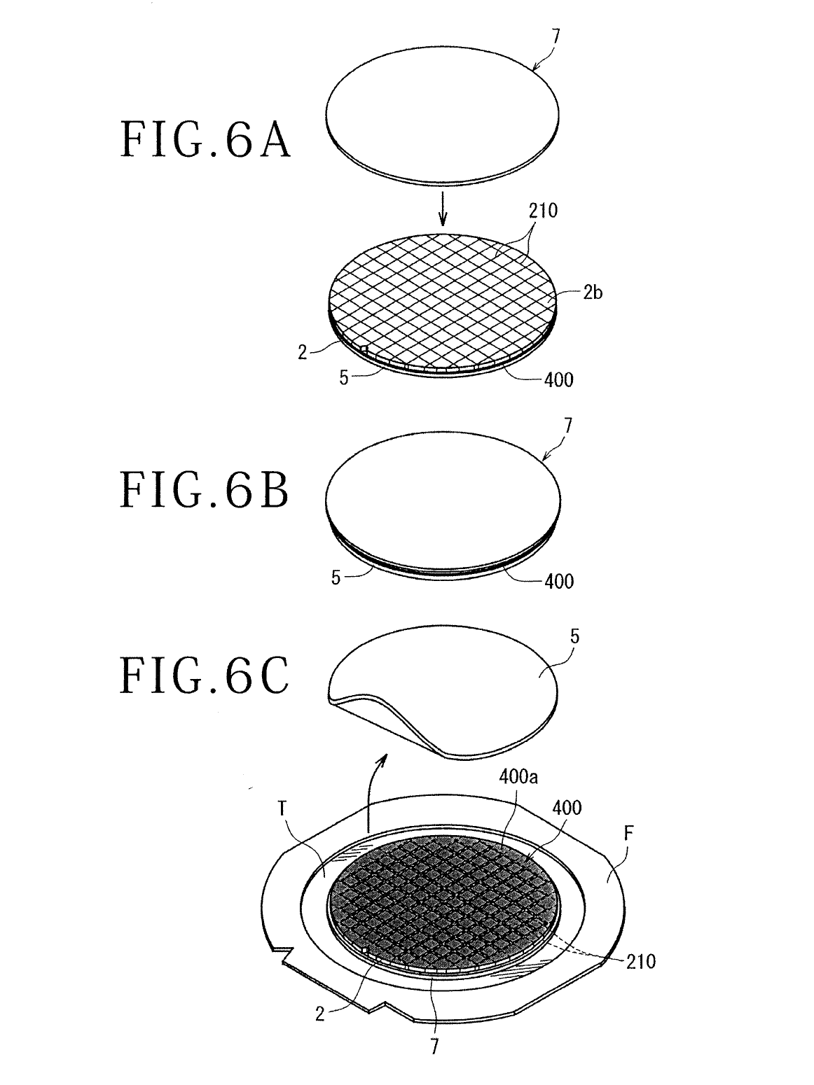

After performing the back grinding step mentioned above, a wafer supporting step is performed in such a manner that an adhesive film is mounted on the back side 2b of the semiconductor wafer 2, a dicing tape is attached to the adhesive film, and the peripheral portion of the dicing tape is supported to an annular frame. A first preferred embodiment of the wafer supporting step will now be described with reference to FIGS. 6A to 6C. As shown in FIGS. 6A and 6B, an adhesive film 7 is mounted on the back side 2b of the semiconductor wafer 2 (adhesive film mounting step). The adhesive film 7 must be reliably mounted on the entire surface of the back side 2b of the semiconductor wafer 2, so that the adhesive film 7 has a size slightly larger than the size of the semiconductor wafer 2. After mounting the adhesive film 7 on the back side 2b of the semiconductor wafer 2 as mentioned above, the adhesive film 7 mounted on the back side 2b of the semiconductor wafer 2 is attached to an expansible dicing tape T supported at its peripheral portion to an annular frame F as shown in FIG. 6C. Thereafter, the protective tape 5 attached to the front side 400a of the protective film 400 formed on the front side 2a of the semiconductor wafer 2 is peeled off as shown in FIG. 6C (protective member peeling step). While the adhesive film 7 mounted on the back side 2b of the semiconductor wafer 2 is attached to the dicing tape T supported to the annular frame F in the first preferred embodiment shown in FIGS. 6A to 6C, the dicing tape T may be attached to the adhesive film 7 mounted on the back side 2b of the semiconductor wafer 2, and at the same time the peripheral portion of the dicing tape T may be supported to the annular frame F.

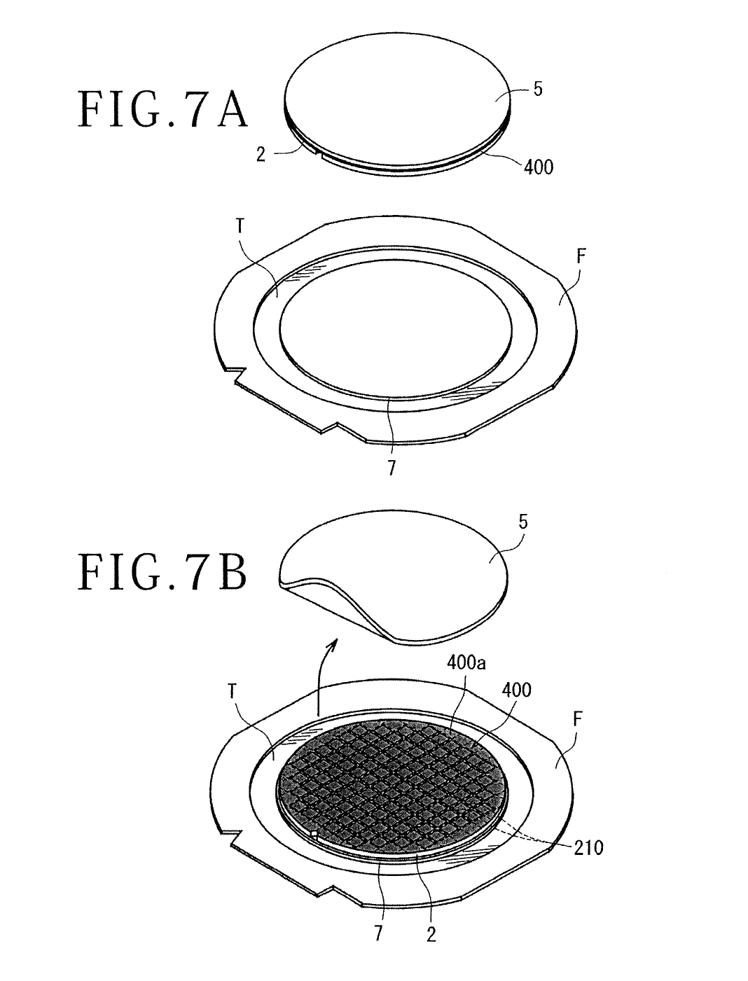

A second preferred embodiment of the wafer supporting step will now be described with reference to FIGS. 7A and 7B. In the second preferred embodiment shown in FIGS. 7A and 7B, an adhesive film 7 is preliminarily attached to a dicing tape T to prepare a dicing tape with adhesive film. More specifically, as shown in FIG. 7A, the dicing tape T is preliminarily supported at its peripheral portion to an annular frame F so as to close the central opening of the annular frame F, and the adhesive film 7 is preliminarily attached to the dicing tape T exposed to the central opening of the annular frame F. Thereafter, as shown in FIG. 7B, the back side 2b of the semiconductor wafer 2 is mounted on the adhesive film 7 attached to the dicing tape T supported to the annular frame F, so that the semiconductor wafer 2 mounted on the adhesive film 7 is supported through the dicing tape T to the annular frame F. As similar to the first preferred embodiment, the adhesive film 7 preliminarily attached to the dicing tape T must be reliably mounted on the entire surface of the back side 2b of the semiconductor wafer 2, so that the adhesive film 7 in the second preferred embodiment also has a size slightly larger than the size of the semiconductor wafer 2. Thereafter, the protective tape 5 attached to the front side 400a of the protective film 400 formed on the front side 2a of the semiconductor wafer 2 is peeled off as shown in FIG. 7B (protective member peeling step). While the back side 2b of the semiconductor wafer 2 is mounted on the adhesive film 7 attached to the dicing tape T supported to the annular frame F in the second preferred embodiment shown in FIGS. 7A and 7B, the adhesive film 7 attached to the dicing tape T may be mounted on the back side 2b of the semiconductor wafer 2, and at the same time the peripheral portion of the dicing tape T may be supported to the annular frame F.

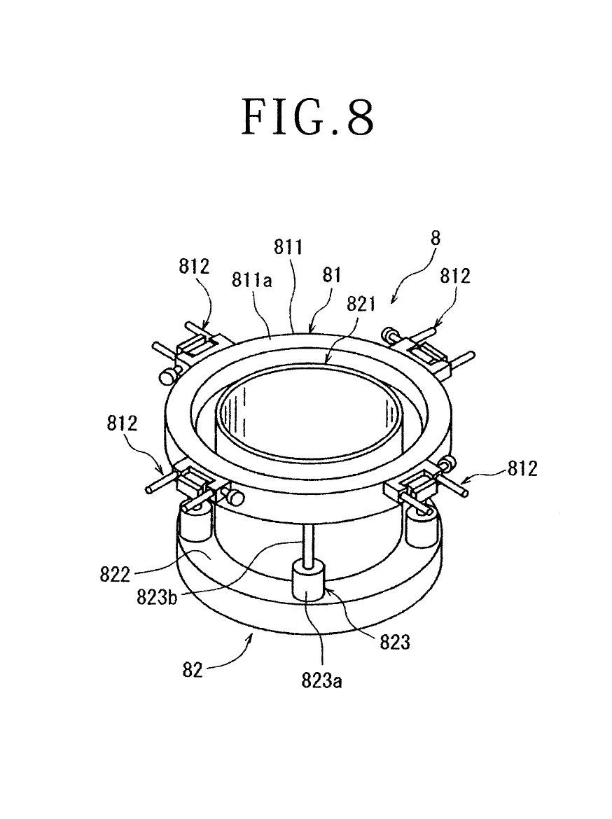

After performing the wafer supporting step mentioned above, an adhesive film breaking step is performed in such a manner that the dicing tape T is expanded to thereby break the adhesive film 7 along the individual device chips 22. This adhesive film breaking step is performed by using a tape expanding apparatus 8 shown in FIG. 8. The tape expanding apparatus 8 shown in FIG. 8 includes frame holding means 81 for holding the annular frame F and tape expanding means 82 for expanding the dicing tape T supported to the annular frame F held by the frame holding means 81. The frame holding means 81 includes an annular frame holding member 811 and a plurality of clamps 812 as fixing means provided on the outer circumference of the frame holding member 811. The upper surface of the frame holding member 811 functions as a mounting surface 811a for mounting the annular frame F thereon. The annular frame F mounted on the frame holding member 811 is fixed to the frame holding member 811 by the clamps 812. The frame holding means 81 is supported by the tape expanding means 82 so as to be vertically movable.

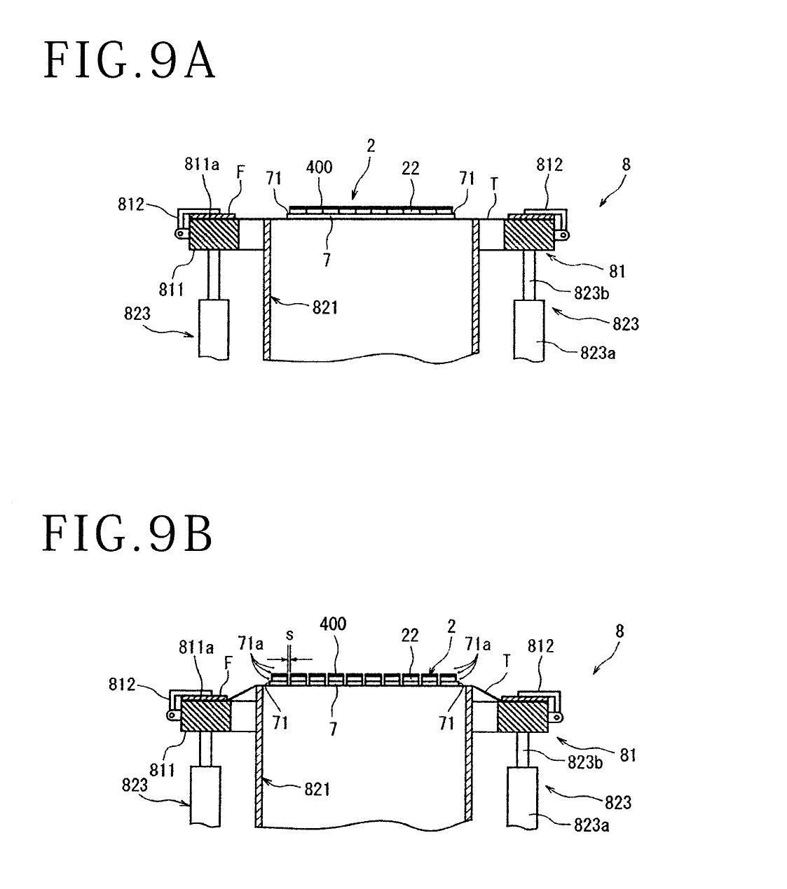

The tape expanding means 82 includes an expanding drum 821 provided inside of the annular frame holding member 811. The expanding drum 821 has an outer diameter smaller than the inner diameter of the annular frame F and an inner diameter larger than the outer diameter of the semiconductor wafer 2 attached to the dicing tape F supported to the annular frame F. The expanding drum 821 has a supporting flange 822 at the lower end of the drum 821. The tape expanding means 82 further includes supporting means 823 for vertically movably supporting the annular frame holding member 811. The supporting means 823 is composed of a plurality of air cylinders 823a provided on the supporting flange 822. Each air cylinder 823a is provided with a piston rod 823b connected to the lower surface of the annular frame holding member 811. The supporting means 823 composed of these plural air cylinders 823a functions to vertically move the annular frame holding member 811 so as to selectively take a reference position where the mounting surface 811a is substantially equal in height to the upper end of the expanding drum 821 as shown in FIG. 9A and an expansion position where the mounting surface 811a is lower in height than the upper end of the expanding drum 821 by a predetermined amount as shown in FIG. 9B.

The adhesive film breaking step using the tape expanding apparatus 8 will now be described with reference to FIGS. 9A and 9B. As shown in FIG. 9A, the annular frame F supporting the semiconductor wafer 2 through the dicing tape T is mounted on the mounting surface 811a of the frame holding member 811 of the frame holding means 81 and fixed to the frame holding member 811 by the clamps 812 (frame holding step). At this time, the frame holding member 811 is set at the reference position shown in FIG. 9A. Thereafter, the air cylinders 823a as the supporting means 823 of the tape expanding means 82 are operated to lower the frame holding member 811 to the expansion position shown in FIG. 9B. Accordingly, the annular frame F fixed to the mounting surface 811a of the frame holding member 811 is also lowered, so that the dicing tape T supported to the annular frame F comes into abutment against the upper end of the expanding drum 821 and is expanded as shown in FIG. 9B (tape expanding step).

Accordingly, a spacing S is formed between any adjacent ones of the individual device chips 22 divided from each other as shown in FIG. 9B, wherein the semiconductor wafer 2 attached through the adhesive film 7 to the dicing tape T has already been divided along the division lines 21. As a result, the adhesive film 7 mounted on the back side 2b of the semiconductor wafer 2 is broken along the device chips 22, so that the adhesive film 7 is divided along the division lines 21 as shown in FIG. 9B. At this time, there is a possibility that the peripheral portion 71 of the adhesive film 7 projecting from the outer circumference of the semiconductor wafer 2 may be partially crushed to scatter as shown by reference symbol 71a in FIG. 9B, so that the crushed part 71a of the peripheral portion 71 of the adhesive film 7 may fall on the front side of the device chips 22. However, since the protective film 400 is formed on the front side of the device chips 22, there is no possibility that the crushed part 71a of the peripheral portion 71 of the adhesive film 7 may directly stick to the front side of the device chips 22. Accordingly, by removing the protective film 400 formed on the front side of the device chips 22 in the next step, the crushed part 71a sticking to the protective film 400 can be removed together with the protective film 400, thereby preventing a reduction in quality of the device chips 22.

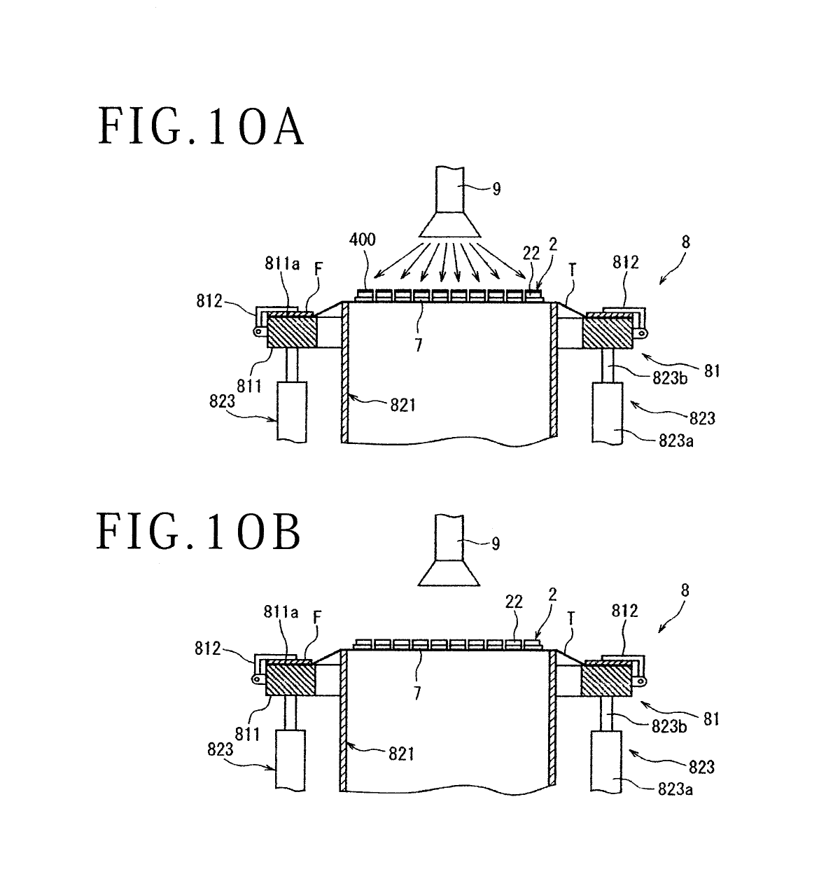

After performing the adhesive film breaking step mentioned above, a protective film removing step is performed in such a manner that a cleaning water is supplied to the protective film 400 formed on the front side of the individual device chips 22, thereby removing the protective film 400. As shown in FIG. 10A, a cleaning water nozzle 9 for supplying a cleaning water is positioned directly above the tape expanding apparatus 8 in the condition shown in FIG. 9B. Thereafter, the cleaning water is supplied from the cleaning water nozzle 9 to the front side (upper surface) of the protective film 400 formed on the front side of the individual device chips 22 attached through the adhesive film 7 to the dicing tape T supported to the annular frame F. As a result, the protective film 400 which is formed of a water-soluble resin can be easily removed by the cleaning water, so that the crushed part 71a sticking to the front side of the protective film 400 can also be removed together with the protective film 400. Accordingly, there is no possibility that a part of the adhesive film 7 (i.e., debris scattered from the peripheral portion 71 of the adhesive film 7) may stick to the front side of each device chip 22 to cause a reduction in quality of the device chips 22.

Although not shown, a pickup step is performed after performing the protective film removing step. That is, each device chip 22 with the adhesive film 7 mounted on the back side is peeled from the dicing tape T in the pickup step.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method of dividing a wafer into a plurality of individual device chips along a plurality of crossing division lines and mounting an adhesive film for die bonding on a back side of each device chip, the plurality of crossing division lines being formed on a front side of the wafer to thereby define a plurality of separate regions where a plurality of devices are respectively formed, the wafer processing method comprising:
a division groove forming step of forming a division groove having a depth corresponding to a finished thickness of each device chip along each division line on the front side of the wafer;
a protective film forming step of applying a water-soluble resin to the front side of the wafer after performing the division groove forming step, thereby forming a protective film from the water-soluble resin on the front side of the wafer;
a protective member attaching step of attaching a protective member to a front side of the protective film after performing the protective film forming step;
a back grinding step of grinding a back side of the wafer until the division groove along each division line is exposed to the back side of the wafer after performing the protective member attaching step, thereby dividing the wafer into the individual device chips;
a wafer supporting step of mounting the adhesive film on the back side of the wafer after performing the back grinding step, attaching a dicing tape to the adhesive film, supporting the peripheral portion of the dicing tape to an annular frame, and peeling the protective member attached to the front side of the wafer;
an adhesive film breaking step of expanding the dicing tape to thereby break the adhesive film along the individual device chips after performing the wafer supporting step; and
a protective film removing step of supplying a cleaning water to the protective film formed on the front side of the wafer after performing the adhesive film breaking step, thereby removing the protective film.
